(19) United States
(12) Patent Application Publication
(10) Pub. No.: US 2024/0178088 A1
(43) Pub. Date: May 30, 2024

(54) PACKAGE SUBSTRATE AND MANUFACTURING METHOD THEREFOR

(71) Applicant: Zhuhai ACCESS Semiconductor Co., Ltd, Guangdong (CN)

(72) Inventors: Xianming CHEN, Guangdong (CN); Gao HUANG, Guangdong (CN); Wenjian LIN, Guangdong (CN); Juchen HUANG, Guangdong (CN); Benxia HUANG, Guangdong (CN)

(21) Appl. No.: 18/377,379

(22) Filed: Oct. 6, 2023

(30) Foreign Application Priority Data
Nov. 25, 2022 (CN) 2022114937226

(51) Int. Cl. H01L 23/31; H01L 21/56; H01L 23/498

(52) U.S. Cl. CPC H01L 23/3121; H01L 21/56; H01L 23/49822

(57) ABSTRACT

A package substrate includes a first dielectric layer, a first line layer provided on the first dielectric layer, the first line layer including a dam, a second dielectric layer provided on the first dielectric layer and covering the first line layer, a component embedded in the second dielectric layer and surrounded by the dam, and a third dielectric layer provided on the second dielectric layer and covering the component. By providing the dam, it can ensure a good bonding force between dielectric layers by using the dam to effectively avoid an offset problem of the components when the same is embedded in the second dielectric layer as well as omitting a step of baking roughening.

### CROSS REFERENCE TO RELATED APPLICATION AND CLAIM OF PRIORITY

This application claims the benefit under 35 USC § 119 of Chinese Patent Application No. 2022114937226, filed on Nov. 25, 2022, in the China Intellectual Property Office, the entire disclosure of which is incorporated herein by reference for all purposes

### BACKGROUND

### 1. Technical Field

The present disclosure relates to the technical field of semiconductors, more particularly to a package substrate and a manufacturing method therefor.

### 2. Background Art

With the continuous development of the electronic industry, the multi-functionality and miniaturization of electronic products have become a development trend. In the field of package substrates, embedding components into a substrate can facilitate electronic products to meet the requirements of high integration, multi-functionality, and miniaturization.

### SUMMARY

In view of the above, it is an object of the present disclosure to propose a package substrate and a manufacturing method therefor.

In view of the above objects, in the first aspect, the present disclosure provides a package substrate including:
a first dielectric layer;
a first line layer provided on the first dielectric layer, the first line layer including a dam;
a second dielectric layer provided on the first dielectric layer and covering the first line layer;
a component embedded in the second dielectric layer and surrounded by the dam; and
a third dielectric layer provided on the second dielectric layer and covering the component.

In some embodiments, the height of the dam is 5 to 50 μm.

In some embodiments, the shape of the dam matches the shape of the component.

In some embodiments, the distance between the periphery of the component and the dam is 5 to 500 μm; and/or
the embedded depth of the component in the dam is ≥1 μm.

In some embodiments, the dam includes at least one opening.

In some embodiments, the thickness of the second dielectric layer between the first dielectric layer and the component is 3 to 30 μm.

In some embodiments, the first dielectric layer includes a groove, the groove being located within the dam.

In some embodiments, the groove has a depth being ≤60 μm.

In some embodiments, the second dielectric layer and the third dielectric layer are a single layer or a multilayer structure.

In the second aspect, the present disclosure provides a manufacturing method for a package substrate, the manufacturing method specifically including:
a) providing a substrate; the substrate including a first dielectric layer and a first line layer located thereon; and the first line layer including a dam;
b) forming a second dielectric layer on the first dielectric layer and the first line layer;
c) mounting a component on the second dielectric layer at a position corresponding to the dam;
d) heating the second dielectric layer to restore a flow, and applying a pressure to the component to embed the component into the second dielectric layer surrounded by the dam along a direction perpendicular to the substrate; and
e) forming a third dielectric layer covering the component on the second dielectric layer.

In some embodiments, the height of the dam is 5 to 50 μm.

In some embodiments, the method includes:
controlling an embedded depth of the component by adjusting the temperature,
the pressure, and extrusion time.

In some embodiments, the embedded depth of the component in the dam is ≥1 μm.

In some embodiments, the distance between the periphery of the component and the dam is 5 to 500 μm; and/or
the thickness of the second dielectric layer between the first dielectric layer and the component is 3 to 30 μm.

In some embodiments, the method includes:
forming a groove on the first dielectric layer, the groove being located within the dam.

In some embodiments, the groove has a depth being ≤60 μm.

From the above, it can be seen that according to the package substrate and the manufacturing method provided in this disclosure, by providing the dam, it can ensure a good bonding force between dielectric layers by using the dam to effectively avoid an offset problem of the components when the same is embedded in the second dielectric layer as well as omitting a step of baking roughening.

### BRIEF DESCRIPTION OF THE DRAWINGS

In order to explain the technical solutions of the present disclosure or in the related art more clearly, the following will briefly introduce the drawings needed in the description of the embodiments and the related art. Obviously, the drawings in the following description are merely embodiments of the present disclosure. For those of ordinary skills in the art, without involving creative efforts, other drawings can be obtained from these drawings. In the drawings, the thickness and shape of some of the layers and regions may be exaggerated for better understanding and ease of description.

FIG. 1 is a schematic cross-sectional diagram of a package substrate provided in an embodiment of the present disclosure;

FIG. 2 is a top view of a partial structure of the package substrate of FIG. 1;

FIG. 3 is a schematic cross-sectional diagram of another package substrate provided in an embodiment of the present disclosure;

FIG. 4 is a schematic diagram of the stress of components in a package substrate provided in an embodiment of the present disclosure;

FIGS. 5A to 5F show schematic cross-sectional views of intermediate structures at various steps of a manufacturing method for a package substrate according to an embodiment of the present disclosure;

FIGS. 6A to 6G show schematic cross-sectional views of intermediate structures at various steps of another manufacturing method for a package substrate according to an embodiment of the present disclosure.

### DETAILED DESCRIPTION OF THE INVENTION

In order to make the purpose, technical solutions, and advantages of this disclosure clearer, the following is a detailed explanation of this disclosure in conjunction with specific embodiments and with reference to the accompanying drawings.

It needs to be noted that unless otherwise defined, technical or scientific terms used in the embodiments of the present disclosure shall have the ordinary meaning as understood by one of ordinary skill in the art to which the present disclosure belongs. The use of “first”, “second”, and similar terms in the embodiments of the present disclosure does not denote any order, quantity, or importance, but rather is used to distinguish different constituting parts. The words “comprising” or “include”, and the like, mean that the elements or articles preceding the word encompass the elements or articles listed after the words and equivalents thereof, but do not exclude other elements or articles. The terms “up”, “down”, “left”, “right”, etc. are only used to represent relative positional relationships. When the absolute position of the described object changes, the relative positional relationship may also change accordingly.

When terms such as “on”, “above”, “below”, and “beside” are used to describe a positional relationship between two parts, one or more parts may be located between the two parts unless the terms are used in conjunction with the terms “immediately adjacent” or “directly”.

When one element or layer is “provided on” another element or layer, the other layer or element can be directly interposed on another element or between them.

In the existing Cavity embedding technology, the components are usually mounted on the resin surface, then baked and cured, and then coated with resin medium, and finally, the electrical conduction between layers is performed.

In order to avoid the position degree deviation of the components due to the hot-press flow of the resin in the subsequent resin coating process, it is necessary to add nitrogen baking after the components mounting to fix the components on the resin surface. Since the resin surface is cured after baking, an additional roughening treatment on the resin surface is often required to perform subsequent resin coating, so as to avoid the problem of poor bonding force between two layers of the resin. But this also tends to lead to the excessive thickness of the resin coating layer, which is not conducive to the manufacturing of interlayer via holes and the reduction of the overall thickness of the substrate.

In view of this, in the first aspect, an embodiment of the present disclosure provides a package substrate, which is advantageous for ensuring good bonding force between dielectric layers by providing a dam and using the dam to effectively avoid an offset problem of the components when the same is embedded in a second dielectric layer as well as omitting a step of baking roughening.

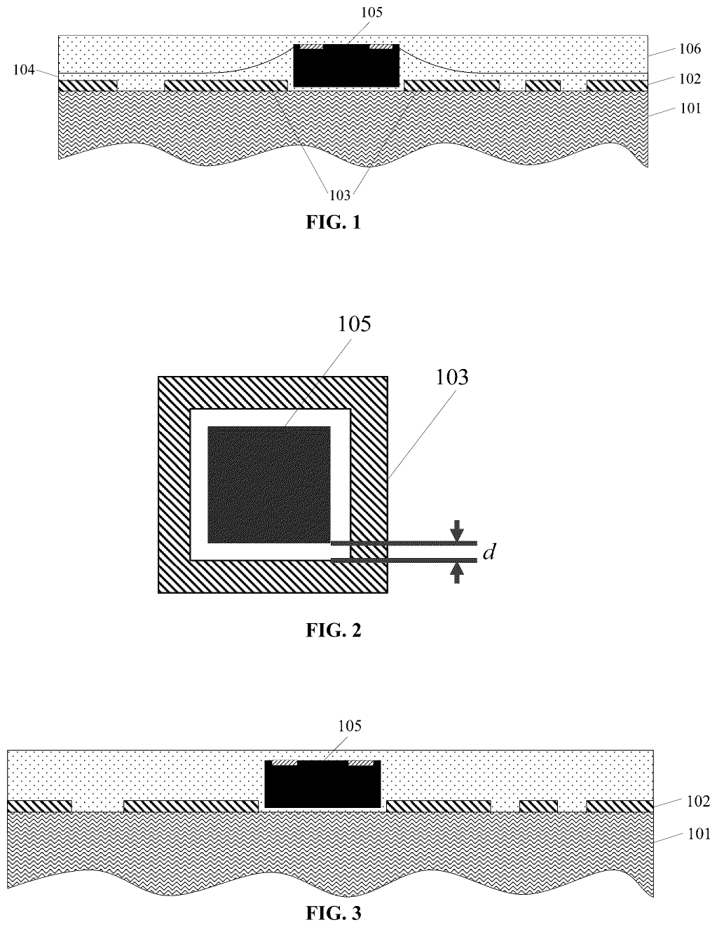

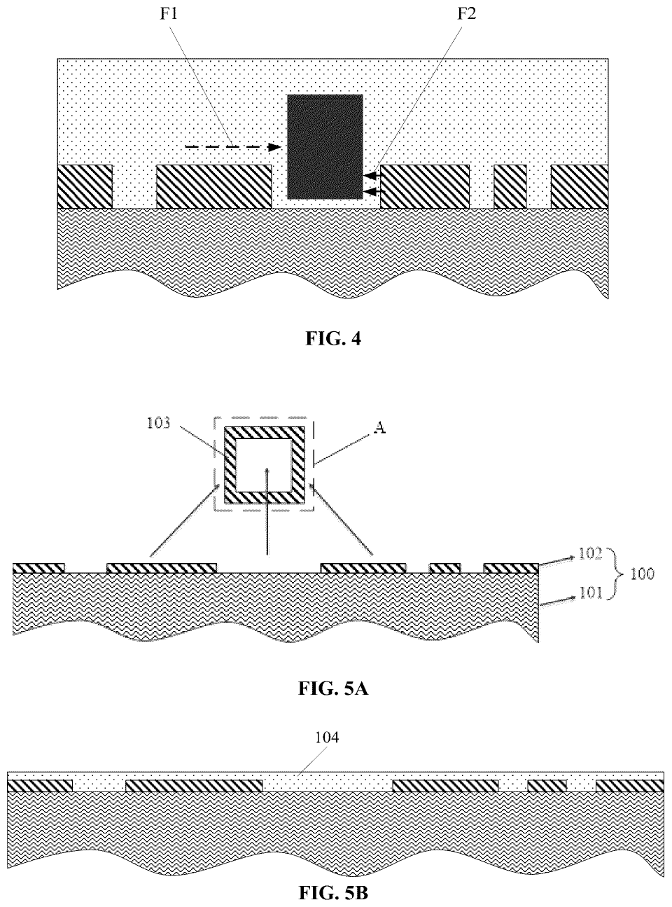

As shown in FIG. 1 to FIG. 3, the package substrate includes a first dielectric layer 101; a first line layer 102 arranged on the first dielectric layer 101, the first line layer including a dam 103 (see FIG. 2); a second dielectric layer 104 provided on the first dielectric layer 101 and covering the first line layer 102; a component 105 embedded in the dam 103, the bottom of the component 105 being in contact with the second dielectric layer 104; and a third dielectric layer 106, which is arranged on the second dielectric layer 104 and covers the component 105.

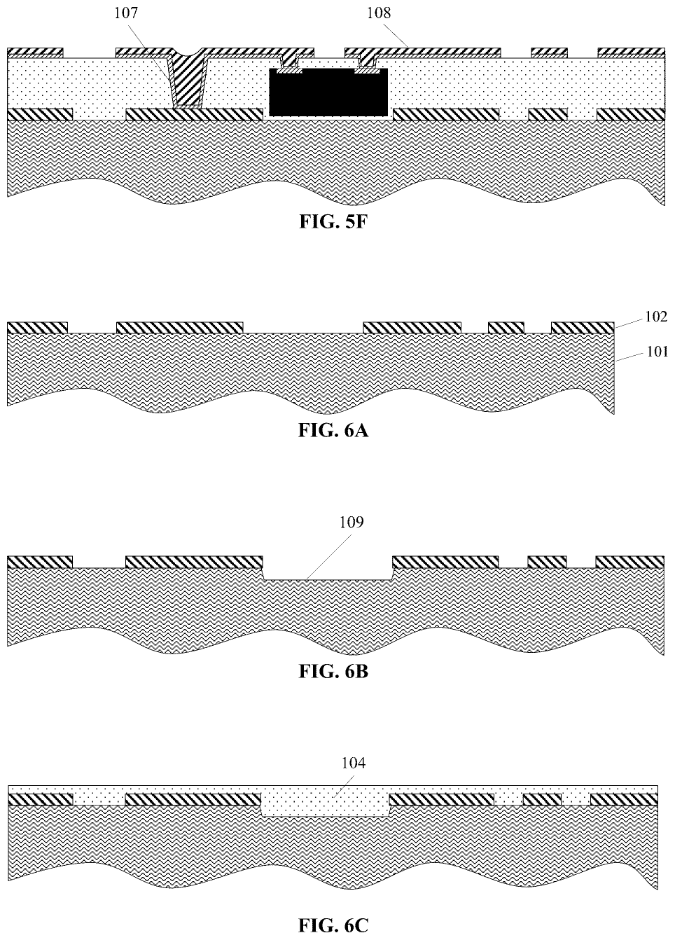

Here, referring to FIG. 4, by replacing nitrogen baking by means of the dam 103, on the one hand, the dam 103 functions to block the flow of the second dielectric layer; on the other hand, the component 105 is subjected to the counteracting force F2 of the “dam” when the component 105 wants to slip due to the unbalanced force F1 and the flow of the pressed-fit dielectric layer; this ensures that component 105 does not offset when being embedded into the second dielectric layer 104 and pressed-fit into the third dielectric layer 106. Furthermore, no baking and no additional step of roughening the surface of the dielectric layer are needed, thus simplifying the manufacturing process and reducing the total thickness of the substrate.

In some embodiments, the first dielectric layer 101 may be a dielectric layer on the surface of a support plate or a substrate, and the material may be, for example, selected from a liquid crystal high molecular polymer, a BT (bismaleimide triazine) resin, a semi-cured Prepreg, an ABF (Ajinomoto Build-up) thin film, an epoxy resin, a polyimide resin, etc., which is not limited by the present disclosure.

In some embodiments, the height of the dam 103 is 5-50 μm, such as 5 μm, 10 μm, 15 μm, 26 μm, 32 μm, 38 μm, 45 μm, or 50 μm. It needs to be noted that if the height of the dam 103 is less than 5 μm, the effect of preventing the dam from offsetting cannot be ensured. Since the dam 103 and the first line layer 102 are manufactured at the same time, if the height of the dam 103 is higher than 50 μm, the manufacturing cost is high and it is unnecessary. Here, the first line layer 102 may be formed by electroplating, and the material may be copper.

The component 105 may be an active element, e.g., a transistor, an IC chip, a logic circuit element, and a power amplifier, or a passive element, e.g., a capacitor, an inductor, a resistor, or a combination thereof. This is not limited by the present disclosure.

At that, the shape of the dam 103 matches the shape of the component 105, e.g., circular, square, etc.

Further, the dam 103 may be a fully enclosed structure (as shown in FIG. 2) or may include at least one opening (not shown). A person skilled in the art could adjust the specific structure of the dam 103 according to needs so as to satisfy actual requirements.

In some embodiments, the embedded depth of the component 105 in the dam 103 is ≥1 μm, e.g., 1 μm, 1.5 μm, and 2 μm.

In some embodiments, the distance d between the periphery of the component 105 and the dam 103 is 5 to 500 μm (as shown in FIG. 2), such as 5 μm, 50 μm, 100 μm, 180 μm, 220 μm, 250 μm, 296 μm, 388 μm, 420 μm, 460 μm, and 500 μm.

In some embodiments, the thickness of the second dielectric layer 104 between the first dielectric layer 101 and the component 105 is 3 to 30 μm, such as 3 μm, 7 μm, 10 μm, 15 μm, 20 μm, 22 μm, and 30 μm.

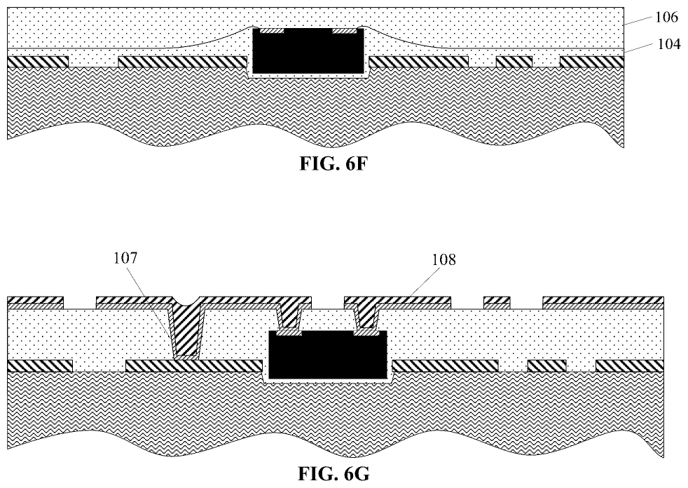

In some embodiments, as shown in FIG. 6B, the first dielectric layer 101 includes a groove 109 located within the dam 103. By providing the groove 109, the depth of the dam 103 can be increased, and the component 105 can be embedded deeper. On the one hand, the component 105 is protected by the “dam” by a larger area during the pressing-fit process of the subsequent process, so that the component 105 does not slip along with the flow of the dielectric layer material. On the other hand, since the embedded depth of the component 105 is deeper, the height of the component 105 is reduced, and the thickness of the final substrate is also reduced.

Optionally, the depth of the groove 109 is ≤60 μm, such as 2 μm, 10 μm, 16 μm, 24 μm, 28 μm, 30 μm, 37 μm, 45 μm, 52 μm, and 60 μm.

In some embodiments, the second dielectric layer 104 and the third dielectric layer 106 may be a single layer or a multi-layer structure. The second dielectric layer 104 and the third dielectric layer 106 may be insulating materials of the same or different materials, such as a resin material, a BT (bismaleimide triazine) resin, a semi-cured Prepreg, an ABF (Ajinomoto Build-up) thin film, an epoxy resin, a polyimide resin, etc. without limitation on the specific types.

It needs to be noted that the presence or absence of a boundary between the second dielectric layer 104 and the third dielectric layer 106 is determined by the chemical characteristics of the resin material. Generally, an interface will not be present if the materials are the same, but it does not mean that an interface will necessarily be present if the materials are different. The interface issue is not limited herein.

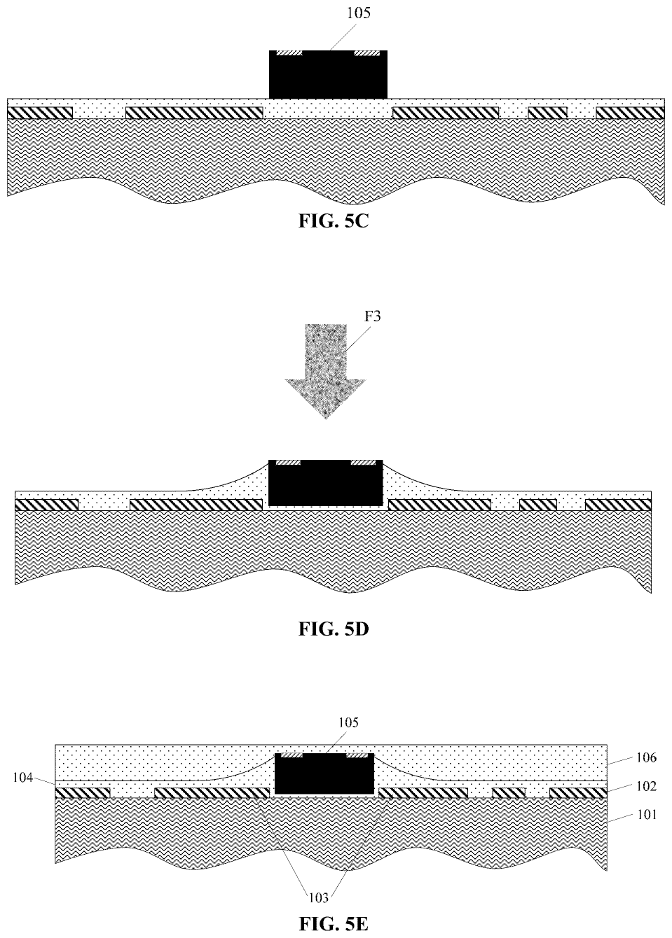

Illustratively, FIG. 1 shows a schematic structural view of the presence of an interface between the second dielectric layer 104 and the third dielectric layer 106. FIG. 3 shows a schematic structural view of the absence of an interface between the second dielectric layer 104 and the third dielectric layer 106.

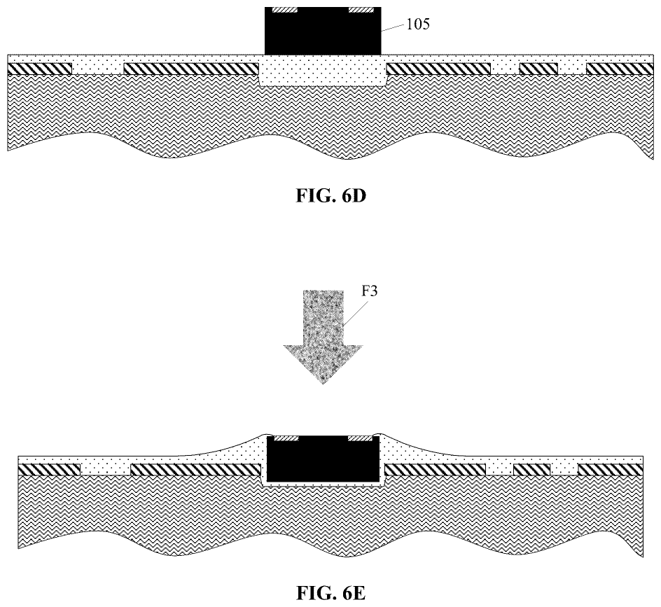

In some embodiments, referring to FIG. 5F, the package substrate further includes a conductive column 107 and a second line layer 108. The second line layer 108 is located on the third dielectric layer 106, and the conductive column 107 is used to connect the first line layer 102 with the second line layer 108.

Here, the present disclosure does not strictly limit the thickness of the third dielectric layer 106, and it suffices to coat the component 105 in it.

In the second aspect, the present disclosure also provides a manufacturing method for a package substrate. With reference to FIGS. 5A to 5F, the manufacturing method includes the following steps: providing a substrate 100—step (a), as shown in FIG. 5A. Here, the substrate 100 is a semi-finished substrate, such as a printed circuit board. The type of a specific semi-finished substrate can be selected according to needs. The subsequent process is only demonstrated as a semi-finished substrate, but the manufacturing method is not limited to only a semi-finished substrate. Optionally, the semi-finished substrate may be manufactured by a masking method process, an MSAP process, or an SAP process, without specific limitations.

Further, the substrate 100 includes a first dielectric layer 101 and a first line layer 102 thereon; the first wiring level 102 includes a dam 103 (shown as a dotted line box A in FIG. 5A). Optionally, the height of the dam 103 is 5 to 50 μm.

Then, a second dielectric layer 104 is formed on the first dielectric layer 101 and the first line layer 102—step (b), as shown in FIG. 5B. Here, the surface of the second dielectric layer 104 is viscous at room temperature or under heating to bond the components.

For example, the second dielectric layer 104 can be formed by coating liquid resin or by pressing fit dry film type dielectric materials with conformal function, without specific limitations.

Next, the component 105 is mounted on the second dielectric layer 104 at a position corresponding to the dam 103—step (c), as shown in FIG. 5C. In some embodiments, the component 105 can be adhered to the second dielectric layer 104 through a chip mounter. During the adhering process, heating can be selected based on the viscosity of the second dielectric layer 104. For example, when the viscosity is low, the component can be heated or a chip mounter with a heating function can be used to heat the semi-finished substrate and then the component 105 is adhered.

The second dielectric layer 104 is then heated to restore the flow and a pressure F3 is applied to the component 105 to embed the component 105 into the second dielectric layer 104 surrounded by the dam 103 along a direction perpendicular to the substrate 100—step (d), as shown in FIG. 5D. In an embodiment, since the component 105 extrudes the second dielectric layer 104, and the crawling glue of the second dielectric layer 104 on the side of the component 105 exists, the heights of the crawling glue are different according to different pressurization parameters, and this is not limited in the present disclosure.

It needs to be noted that the embedding depth of the component 105 is controlled by adjusting the temperature, pressure, and extrusion time. The specific parameters of the temperature, pressure, and extrusion time can be adjusted according to actual conditions and are not limited herein.

Optionally, the embedded depth of the component 105 with respect to the dam 103 is ≥1 μm. Optionally, the distance between the periphery of the component 105 and the dam 103 is 5-500 μm. Optionally, the thickness of the second dielectric layer 104 between the first dielectric layer 101 and the component 105 is 3-30 μm.

Next, the third dielectric layer 106 covering the component 105 is formed on the second dielectric layer 104—step (e), as shown in FIG. 5E. It needs to be noted that the third dielectric layer 106 is formed in a similar manner to the second dielectric layer 104, which will not be described in detail.

The third dielectric layer 106 and the second dielectric layer 104 may be insulating materials of the same or different materials, such as a resin material, a BT (bismaleimide triazine) resin, a semi-cured Prepreg, an ABF (Ajinomoto Build-up) thin film, an epoxy resin, a polyimide resin, etc. without limitation on the specific types.

Then, an interlayer conductive blind hole is made to form a second line layer 108 and a conductive column 107—step (f), as shown in FIG. 5F. Here, the conductive blind hole may be opened by laser drilling, and the second line layer 108 and the conductive column 107 may be formed by electroplating. This is not specifically limited by the present disclosure.

The present disclosure also provides another manufacturing method for a package substrate. Since the manufacturing method is the same as most steps of the aforementioned method, it is briefly described here as follows.

With reference to FIGS. 6A to 6G, the manufacturing method includes the following steps: providing a substrate 100—step (a), as shown in FIG. 6A.

Then, a groove 109 is formed on the first dielectric layer 101, and the groove 109 is located in the dam 103—step (b), as shown in FIG. 6B. Here, the resin dielectric layer in the “dam” is thinned by means of Plasma, sand blasting, depth-controlled mechanical milling, laser ablation, etching, etc. so that groove 109 is formed on the first dielectric layer 101, resulting in a longitudinally deeper “dam”. The present disclosure does not limit the manner in which the “groove” is formed.

Optionally, the groove has a depth being ≤60 μm. By providing the groove 109, the depth of the dam 103 can be increased, and the component 105 can be embedded deeper. On the one hand, the component 105 is protected by the “dam” by a larger area during the pressing-fit process of the subsequent process, so that the component 105 does not slip along with the flow of the dielectric layer material. On the other hand, since the embedded depth of the component 105 is deeper, the height of the component 105 is reduced, and the thickness of the final substrate is also reduced.

Next, a second dielectric layer 104 is formed on the first dielectric layer 101 and the first line layer 102—step (c), as shown in FIG. 6C.

Then, the component 105 is mounted on the second dielectric layer 104 at a position corresponding to the dam 103—step (d), as shown in FIG. 6D.

Next, the second dielectric layer 104 is heated to resume the flow, and a pressure F3 is applied to the component 105 to embed the component 105 into the dam 103 in a direction perpendicular to the substrate 100—step (e), as shown in FIG. 6E.

Then, the third dielectric layer 106 covering the component 105 is formed on the second dielectric layer 104—step (f), as shown in FIG. 6F.

Next, an interlayer conductive blind hole is made to form a second line layer 108 and a conductive column 107—step (g), as shown in FIG. 6G.

Those of ordinary skills in the art should understand that the discussion of any of the above embodiments is only illustrative and is not intended to imply that the scope of the present disclosure (including the claims) is limited to these examples; under the concept of this disclosure, the technical features of the above embodiments or different embodiments can also be combined, and the steps can be implemented in any order, there are many other changes in different aspects of the embodiments of the disclosure as described above, which are not provided in detail for clarity.

The disclosed embodiments are intended to cover all such alternatives, modifications, and variances which fall within the broad scope of the appended claims. Therefore, any omissions, modifications, equivalent substitutions, improvements, etc. made within the spirit and principles of the disclosed embodiments shall be included in the scope of protection of the present disclosure.

What is claimed is:

1. A package substrate comprising:
a first dielectric layer;
a first line layer provided on the first dielectric layer, the first line layer comprising a dam;
a second dielectric layer provided on the first dielectric layer and covering the first line layer;
a component embedded in the second dielectric layer and surrounded by the dam; and
a third dielectric layer provided on the second dielectric layer and covering the component.

2. The package substrate according to claim 1, wherein a height of the dam is 5 to 50 μm.

3. The package substrate according to claim 1, wherein a shape of the dam matches a shape of the component.

4. The package substrate according to claim 1, wherein a distance between a periphery of the component and the dam is 5 to 500 μm; and/or an embedded depth of the component in the dam is equal to or greater than 1 μm.

5. The package substrate according to claim 1, wherein the dam comprises at least one opening.

6. The package substrate according to claim 1, wherein a thickness of the second dielectric layer between the first dielectric layer and the component is 3 to 30 μm.

7. The package substrate according to claim 1, wherein the first dielectric layer comprises a groove, the groove being located within the dam.

8. The package substrate according to claim 7, wherein a depth of the groove is equal to or less than 60 μm.

9. The package substrate according to claim 1, wherein the second dielectric layer and the third dielectric layer are a single layer or a multilayer structure.

10. A manufacturing method for a package substrate, the manufacturing method comprising:
providing a substrate; the substrate comprising a first dielectric layer and a first line layer located thereon; and the first line layer comprising a dam;
forming a second dielectric layer on the first dielectric layer and the first line layer;
mounting a component on the second dielectric layer at a position corresponding to the dam;
heating the second dielectric layer to restore a flow, and applying a pressure to the component to embed the component into the second dielectric layer surrounded by the dam along a direction perpendicular to the substrate; and
forming a third dielectric layer covering the component on the second dielectric layer.

11. The manufacturing method according to claim 10, wherein a height of the dam is 5 to 50 μm.

12. The manufacturing method according to claim 10, further comprising:
controlling an embedded depth of the component by adjusting a temperature, a pressure, and extrusion time.

13. The manufacturing method according to claim 10, wherein an embedded depth of the component in the dam is equal to or greater than 1 μm.

14. The manufacturing method according to claim 10, wherein a distance between a periphery of the component and the dam is 5 to 500 μm; and/or
a thickness of the second dielectric layer between the first dielectric layer and the component is 3 to 30 μm.

15. The manufacturing method according to claim 10, further comprising:
forming a groove on the first dielectric layer, the groove being located within the dam.

16. The manufacturing method according to claim 15, wherein a depth of the groove is equal to or less than 60 μm.
